(19) United States
(12) Patent Application Publication
(10) Pub. No.: US 2004/0109349 A1
(43) Pub. Date: Jun. 10, 2004

(54) Magnetic memory device with divided write wirings

(76) Inventors: Kentaro Nakajima, Tokyo (JP); Yoshiaki Asao, Yokohama-shi (JP); Keiji Hosotani, Tokyo (JP); Masayuki Sagoi, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/660,677

(22) Filed: Sep. 12, 2003

(30) Foreign Application Priority Data
Sep. 13, 2002 (JP) 2002-268269

(51) Int. Cl. G11C 11/00

(52) U.S. Cl. 365/158; 365/63

(57) ABSTRACT

A magnetic memory device includes first wirings which run in the first direction and are divided in the second direction different from the first direction, a second wiring which runs in the second direction, and a first magneto-resistive element which is arranged across the first divided wirings near the intersection of the first and second wirings in the first memory cell region.

### CROSS-REFERENCE TO RELATED APPLICATIONS

This application is based upon and claims the benefit of priority from the prior Japanese Patent Application No. 2002-268269, filed Sep. 13, 2002, the entire contents of which are incorporated herein by reference.

### BACKGROUND OF THE INVENTION

1. Field of the Invention

The present invention relates to an information reproduction technique using a ferromagnet and, more particularly, to a magnetic memory device using a magneto-resistive element.

2. Description of the Related Art

A magnetic random access memory (to be simply referred to as an MRAM hereinafter) is a general term for solid-state memories capable of properly writing, holding, and reading out recording information by using the magnetization direction of a ferromagnet as an information recording medium.

The memory cell of the MRAM generally has a layered structure of a plurality of ferromagnetic layers. Information is recorded by changing the relative magnetization layout of a plurality of ferromagnetic layers which constitute a memory cell to be parallel or antiparallel, and making the parallel or antiparallel state correspond to binary information “1” or “0”. Recording information is written by supplying a current to write wirings laid out in cross stripes, and switching the magnetization direction of the ferromagnet of each cell by a current magnetic field generated by the current. This MRAM is a nonvolatile memory in which power consumption in record holding is 0 in principle and the record is held even upon power-off. Recording information is read out using a phenomenon so called magneto-resistance in which the electrical resistance of a memory cell changes depending on the relative angle between the magnetization direction of a ferromagnet which constitutes a cell and the sense current or the relative magnetization angle between a plurality of ferromagnetic layers.

From a comparison between the MRAM function and the function of a semiconductor memory using a conventional dielectric, the MRAM has many advantages: (1) the MRAM is complete nonvolatile and enables 10¹⁵ or more rewrite operations, (2) the MRAM realizes nondestructive read and can shorten the read cycle because of no need for refresh operation, and (3) the MRAM is more resistant to radiation than a charge storage memory cell. The degree of integration per unit area and the write and read times of the MRAM are estimated to be almost equal to those of a DRAM. Hence, the MRAM is expected to be applied to the external recording device of a portable device, LSI embedding purpose, and the main memory of a personal computer by fully exploiting a significant nonvolatile feature.

MRAMs which are being examined for practical use employ an element exhibiting tunnel magneto-resistance (to be simply referred to as a TMR effect hereinafter) for a memory cell (see, e.g., nonpatent reference 1). The element exhibiting the TMR effect (to be simply referred to as an MTJ (Magnetic Tunnel Junction) element hereinafter) is mainly formed from a three-layered film of a ferromagnetic layer/insulating layer/ferromagnetic layer, and the current tunnels through the insulating layer. The tunnel resistance value changes in proportion to the cosine of the relative magnetization angle between the two ferromagnetic metal layers, and takes a maximum value when the magnetization directions are antiparallel. In a tunnel junction of, e.g., NiFe/Co/Al₂O₃/Co/NiFe, a magneto-resistance change ratio exceeding 25% was found in a low magnetic field of 50 OeV or less (see, e.g., nonpatent reference 2). Known examples of the MTJ element structure are a so-called spin valve structure (see, e.g., nonpatent reference 3) in which an antiferromagnet is arranged in contact with one ferromagnet to pin the magnetization direction in order to increase the magnetic field sensitivity, and a structure (see, e.g., nonpatent reference 4) in which double tunnel barriers are arranged to improve the bias dependence of the magneto-resistance change ratio.

However, in order to develop an MRAM having the degree of integration in Gb class or more, several problems are left unsolved.

One of the problems in MRAM development is a decrease in write current. In a conventionally proposed MRAM, as shown in FIGS. 21 and 22, a current is supplied to wirings wwl and bl to switch magnetization of the recording layer of a magneto-resistive element (MTJ element) 11 by a magnetic field generated by the current. The magnetic field intensity generated by the wirings wwl and bl changes depending on the current values of the wirings wwl and bl and the distances between the wirings wwl and bl and the magneto-resistive element 11. Conventionally known reports show a magnetic field intensity of about several Oe/mA. The magnetization switching threshold (to be referred to as a switching magnetic field Hsw hereinafter) of the recording layer of the magneto-resistive element 11 increases in inverse proportion to the size (to be defined as a cell width w hereinafter) of the magneto-resistive element 11 in the hard axis of magnetization, as represented by equation (1). In equation (1), a conventionally known value A is 10 to 20 Oem.

Hsw=Hsw⁰+A/w (1)

Considering the reliability of the wiring, electro-migration poses one limitation. Electromigration is accelerated by the current density of the wiring. The upper limits of current densities in an Al—Cu wiring and Cu wiring currently used for LSI manufacture are about 10 mA/m² and 100 mA/m², respectively. Assuming manufacture by a 0.1-m rule necessary to realize the degree of integration in Gb class, the upper limit of a current value which can be supplied to a wiring even in the use of a Cu wiring is about 1 mA, and the value of a magnetic field generated by this current is about several Oe. The switching magnetic field of a magneto-resistive element about 0.1 m in size is several ten Oe or more in accordance with equation (1). That is, it is very difficult to implement a Gb-class MRAM by the current technique.

To solve this problem, an example in which a keeper layer or yoke structure of a high-permeability magnetic material is arranged around a wiring has been proposed, as disclosed in patent documents 1, 2, 3, and 4. These methods are to improve a magnetic field generated near a magneto-resistive element and reduce the write current value by converging a magnetic flux generated around a wiring into the keeper layer or yoke structure. Also, methods disclosed in patent documents 5, 6, 7, and 8 are known as an example in which the write current value is reduced by changing the layout of a wiring and magneto-resistive element. Methods disclosed in patent documents 9, 10, and 11 are known as an example in which the relative angle between the current direction in write and the easy axis of magnetization of a magneto-resistive element is properly controlled to increase the tolerance of the write current value.

(Nonpatent Reference 1)

Roy Scheuerlein, et al., A 10 ns Read and Write Non-Volatile Memory Array Using a Magnetic Tunnel Junction and FET Switch in each Cell, “2000 ISSCC Digest of Technical Papers”, (USA), 2000, February, pp. 128-129

(Nonpatent Reference 2)

M Sato, et al., Spin-Valve-Like Properties and Annealing Effect in Ferromagnetic Tunnel Junctions, “IEEE Trans. Mag.”, (USA), 1997, Vol. 33, No. 5, pp. 3553-3555

(Nonpatent Reference 3)

M Sato, et al., Spin-Valve-Like Properties of Ferromagnetic Tunnel Junctions, “Jpn. J. Appl. Phys.”, 1997, Vol. 36, Part 2, pp. 200-201

(Nonpatent Reference 4)

K Inomata, et al., Spin-dependent tunneling between a soft ferromagnetic layer and hard magnetic nano particles, “Jpn. J. Appl. Phys.”, 1997, Vol. 36, Part 2, pp. 1380-1383

(Patent Reference 1)

U.S. Pat. No. 5,940,319

(Patent Reference 2)

U.S. Pat. No. 5,956,267

(Patent Reference 3)

Pamphlet of International Publication No. 00/10172

(Patent Reference 4)

Jpn. Pat. Appln. KOKAI Publication No. 8-306014

(Patent Reference 5)

U.S. Pat. No. 5,946,228

(Patent Reference 6)

U.S. Pat. No. 6,072,718

(Patent Reference 7)

U.S. Pat. No. 6,104,633

(Patent Reference 8)

U.S. Pat. No. 6,005,800

(Patent Reference 9)

U.S. Pat. No. 6,081,445

(Patent Reference 10)

U.S. Pat. No. 6,134,139

(Patent Reference 11)

U.S. Pat. No. 6,005,800

### BRIEF SUMMARY OF THE INVENTION

A magnetic memory device according to an aspect of the present invention comprises first wirings which run in a first direction and are divided in a second direction different from the first direction, a second wiring which runs in the second direction, and a first magneto-resistive element which is arranged across the first divided wirings near an intersection of the first and second wirings in a first memory cell region.

### BRIEF DESCRIPTION OF THE SEVERAL VIEWS OF THE DRAWING

FIG. 1 is a schematic plan view showing a magnetic memory device according to the first embodiment of the present invention;

FIG. 2 is a sectional view showing the magnetic memory device taken along the line II-II in FIG. 1;

FIGS. 3, 4, 5, 6, and 7 include portions (a) and portions (b), the portions (a) are graphs each showing the magnetic field distribution of a write current in the first embodiment and the prior art, the portions (b) are sectional views each showing a write word line in the first embodiment and the prior art;

FIG. 8 is a view showing a change in magnetization of a ferromagnet according to the first embodiment of the present invention;

FIG. 9 is a schematic plan view showing a magnetic memory device according to the second embodiment of the present invention;

FIG. 10 is a sectional view showing the magnetic memory device taken along the line X-X in FIG. 9;

FIG. 11 is a sectional view showing a magnetic memory device according to the third embodiment of the present invention;

FIG. 12 is a sectional view showing another magnetic memory device according to the third embodiment of the present invention;

FIG. 13 is a schematic plan view showing a magnetic memory device according to the fourth embodiment of the present invention;

FIG. 14 is a sectional view showing the magnetic memory device taken along the line XIV-XIV in FIG. 13;

FIG. 15 is a plan view showing another magnetic memory device according to the fourth embodiment of the present invention;

FIG. 16 is a sectional view showing the magnetic memory device taken along the line XVI-XVI in FIG. 15;

FIG. 17 is a schematic plan view showing a magnetic memory device according to the fifth embodiment of the present invention;

FIG. 18 is a sectional view showing the magnetic memory device taken along the line XVIII-XVIII in FIG. 17;

FIG. 19 is a schematic plan view showing another magnetic memory device according to the fifth embodiment of the present invention;

FIG. 20 is a sectional view showing the magnetic memory device taken along the line XX-XX in FIG. 19;

FIG. 21 is a schematic plan view showing a conventional magnetic memory device; and

FIG. 22 is a sectional view showing the magnetic memory device taken along the line XXII-XXII in FIG. 21.

### DETAILED DESCRIPTION OF THE INVENTION

Preferred embodiments of the present invention will be described below with reference to the several views of the accompanying drawing. In the following description, the same reference numerals denote the same parts throughout the drawing.

[First Embodiment]

In the first embodiment, a write word line for one magneto-resistive element is divided into a plurality of lines on the same plane.

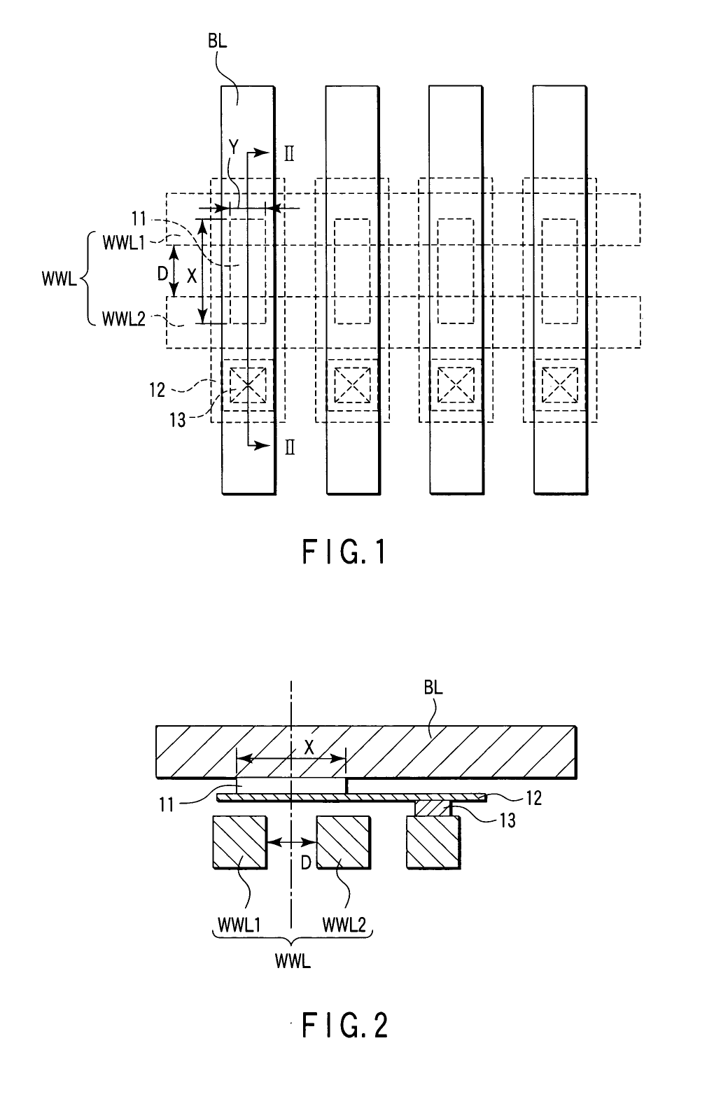

FIG. 1 is a schematic plan view showing a magnetic memory device according to the first embodiment of the present invention. FIG. 2 is a sectional view showing the magnetic memory device taken along the line II-II in FIG. 1.

As shown in FIGS. 1 and 2, a magneto-resistive element 11 is arranged between a bit line BL and a write word line WWL near the intersection of the bit line BL and write word line WWL. The bit line BL is connected to the upper surface of the magneto-resistive element 11. A switching element (not shown) such as a MOS transistor is connected to the lower surface of the magneto-resistive element 11 via a lower metal layer 12 and contact 13.

In the magnetic memory device according to the first embodiment, a plurality of divided write word lines WWL1 and WWL2 are arranged on the same plane for one magneto-resistive element 11. The write word lines WWL1 and WWL2 are divided in a direction different from the running direction, i.e., the direction of length X (easy axis of magnetization) of the magneto-resistive element 11. An interval D between the write word lines WWL1 and WWL2 is smaller than the length X of the magneto-resistive element 11. The magneto-resistive element 11 is arranged across the write word lines WWL1 and WWL2.

The magneto-resistive element 11 desirably has a rectangular shape at an aspect ratio of 1 or more such that the length X is larger than a width Y. This is to increase the squareness ratio in a remanent magnetization state and to reduce the magnetic field threshold in magnetization switching and variations in threshold. In order to form the magneto-resistive element 11, the width Y is set to a minimum processing size in processing. The length X becomes larger than the minimum processing size, providing a rectangular shape at an aspect ratio of 1 or more.

Write of data in the magneto-resistive element 11 uses the bit line BL and the write word lines WWL1 and WWL2. Read of data written in the magneto-resistive element 11 uses the bit line BL and a switching element. When a MOS transistor is used as the switching element, the gate of the MOS transistor functions as a read word line.

The magneto-resistive element 11 is, e.g., an MTJ (Magnetic Tunnel Junction) element comprised of a magnetization-pinned layer (magnetic layer) whose magnetization direction is pinned, a tunnel junction layer (nonmagnetic layer), and a magnetic recording layer (magnetic layer) whose magnetization direction is switched. The MTJ element may have a single-tunnel junction structure formed from one tunnel junction layer as described above, or a double-tunnel junction structure formed from two tunnel junction layers. At least one of the magnetization-pinned layer and magnetic recording layer may have a three-layered structure formed from a ferromagnetic layer, nonmagnetic layer, and ferromagnetic layer.

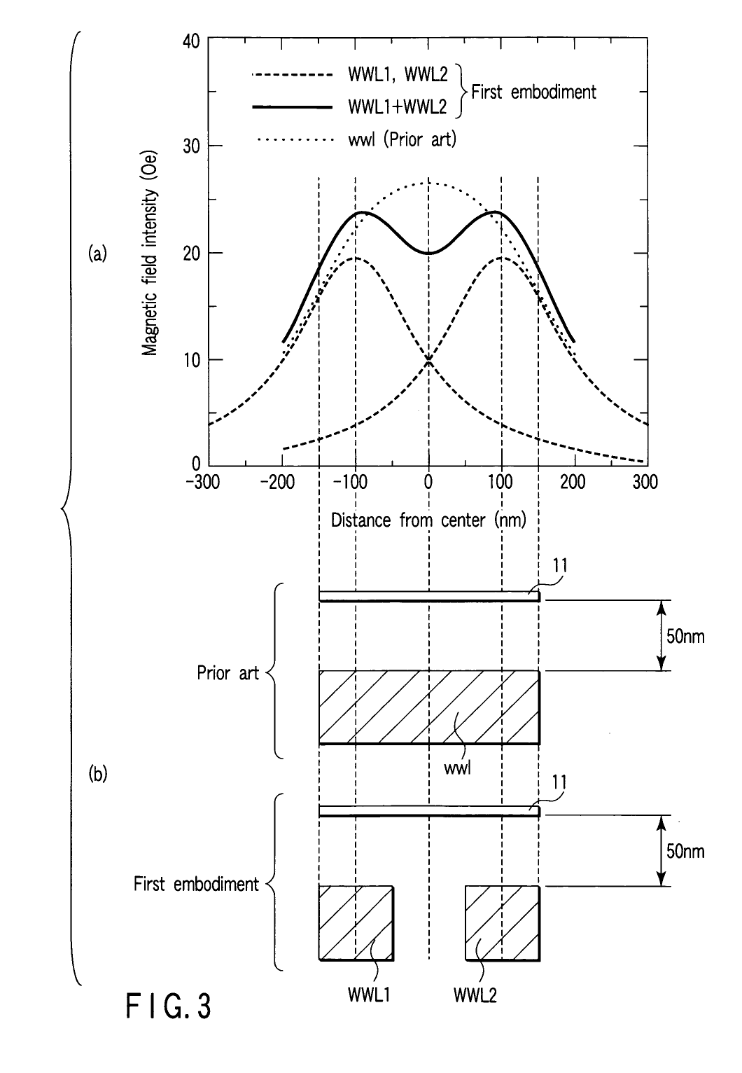

According to the first embodiment, the magnetic field distribution of the write current near the magneto-resistive element 11 is different form that in a case wherein the write word line is not divided. This will be explained in detail with reference to FIG. 3 to FIG. 7.

In the portions (a) of FIG. 3 to FIG. 7, the broken lines represent the intensities of magnetic fields generated by the write word lines WWL1 and WWL2 in the first embodiment. The solid line represents the magnetic field intensity as the sum of magnetic fields generated by the write word lines WWL1 and WWL2 in the first embodiment. The dotted line represents the intensity of a magnetic field generated by a conventional undivided write word line wwl. The portions (a) of FIG. 3 to FIG. 7 show the one-dimensional distributions of magnetic fields at points apart from the surfaces of the write word lines WWL1, WWL2, and wwl.

In the portions (b) of FIG. 3 to FIG. 7, in the first embodiment, a current of 1 mA is supplied to the write word lines WWL1 and WWL2. In the prior art, a current of 2 mA is supplied to the write word line wwl. That is, the sum of current values supplied to the write word lines WWL1 and WWL2 in the first embodiment is equal to a current value supplied to the write word line wwl in the prior art.

The portion (a) of FIG. 3 shows the difference in magnetic field intensity distribution when the positions of the ends of the write word lines WWL1 and WWL2 and the conventional write word line wwl coincide with those of the ends of the magneto-resistive element 11. As shown in the portion (b) of FIG. 3, the write word lines WWL1 and WWL2 in the first embodiment are arranged as a square of 100 nm in width×100 nm in height at an interval of 100 nm on the same plane. The conventional write word line wwl is a rectangle of 300 nm in width×100 nm in height. In this case, the combined magnetic field intensity in the first embodiment decreases at the center of the magneto-resistive element 11, but increases near the end of the magneto-resistive element 11, compared to the prior art.

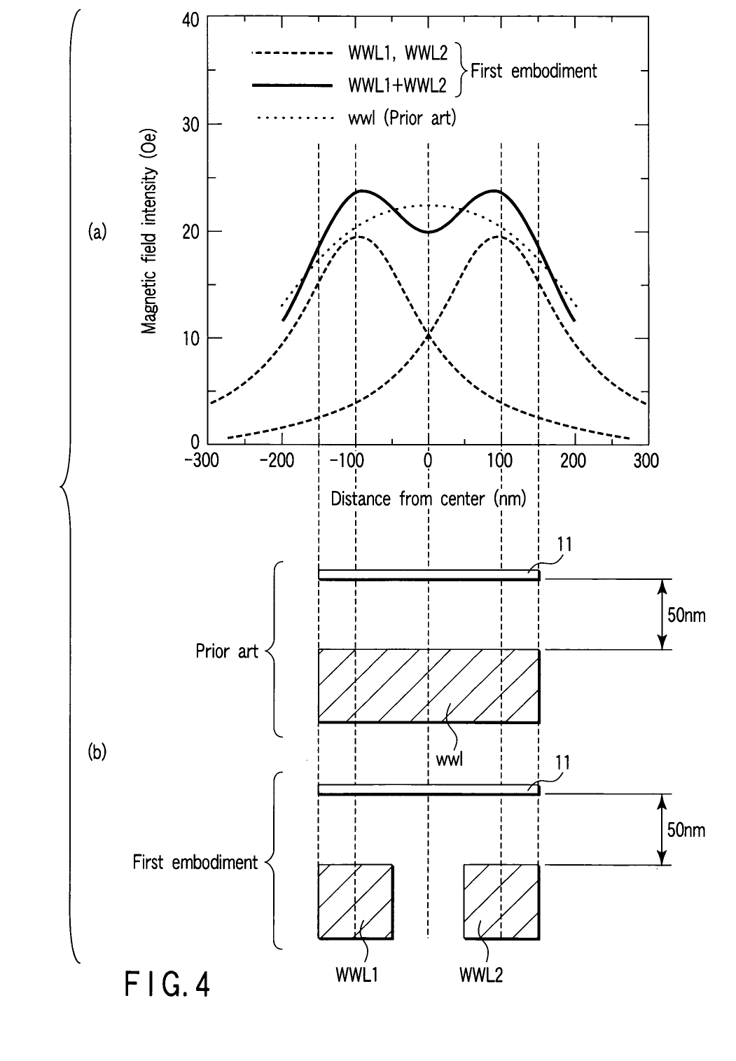

The portion (a) of FIG. 4 shows the difference in magnetic field intensity distribution when the positions of the ends of the write word lines WWL1 and WWL2 coincide with those of the ends of the magneto-resistive element 11, and the positions of the ends of the conventional write word line wwl are located outside the ends of the magneto-resistive element 11. As shown in the portion (b) of FIG. 4, the write word lines WWL1 and WWL2 in the first embodiment are arranged as a square of 100 nm in width×100 nm in height at an interval of 100 nm on the same plane. The conventional write word line wwl is a rectangle of 400 nm in width×100 nm in height. In this case, similar to the portion (a) of FIG. 3, the combined magnetic field intensity in the first embodiment decreases at the center of the magneto-resistive element 11, but increases near the end of the magneto-resistive element 11, compared to the prior art. Further, the combined magnetic field intensity in the first embodiment is much higher near the end of the magneto-resistive element 11 in the portion (a) of FIG. 4 than the prior art, in comparison with the portion (a) of FIG. 3. That is, as the conventional write word line wwl has a higher ratio of the width and height, the effect of increasing the magnetic field intensity near the end of the magneto-resistive element 11 when the wiring is divided can be more enhanced.

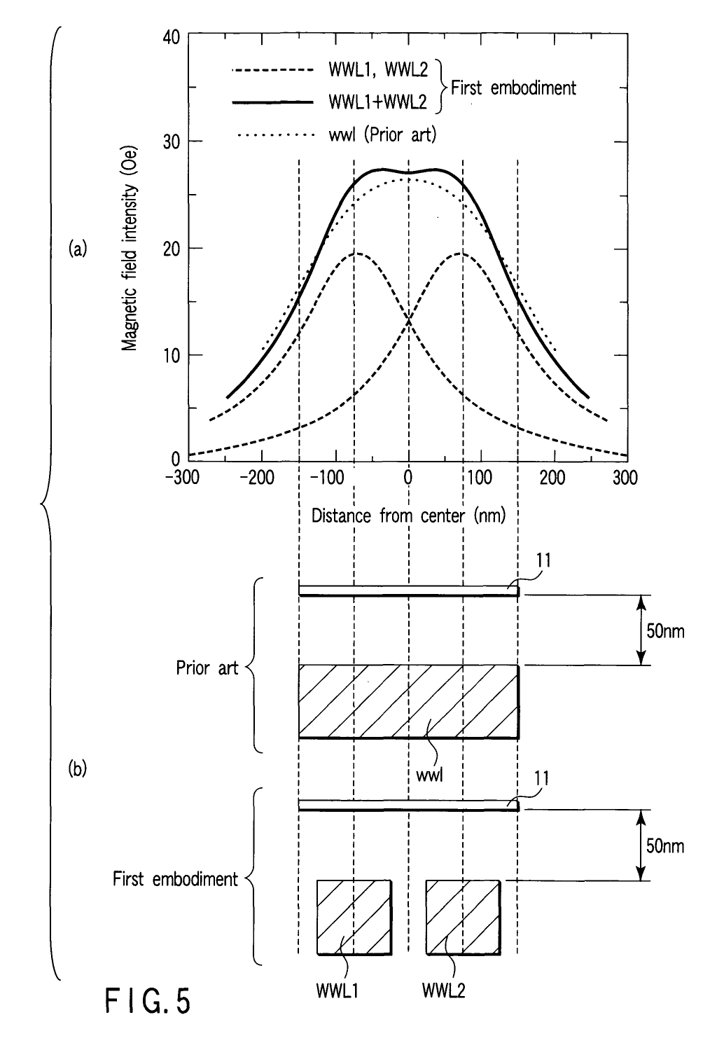

The portion (a) of FIG. 5 shows the difference in magnetic field intensity distribution when the positions of the ends of the write word lines WWL1 and WWL2 are located inside the ends of the magneto-resistive element 11, and the positions of the ends of the conventional write word line wwl coincide with those of the ends of the magneto-resistive element 11. As shown in the portion (b) of FIG. 5, the write word lines WWL1 and WWL2 in the first embodiment are arranged as a square of 100 nm in width×100 nm in height on the same plane at a smaller interval of 50 nm than those in the portions (a) of FIGS. 3 and 4. The conventional write word line wwl is a rectangle of 300 nm in width×100 nm in height. In this case, unlike the portion (a) of FIG. 3, the first embodiment can obtain a higher-intensity combined magnetic field with a more uniform combined magnetic field distribution within the plane of the magneto-resistive element 11.

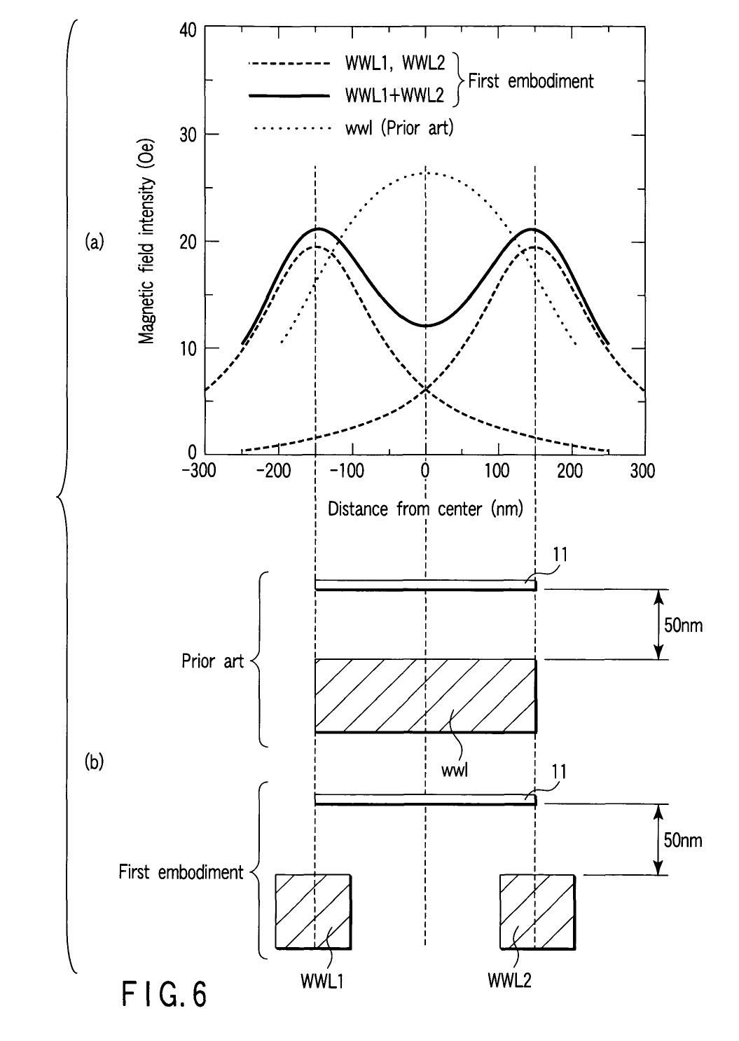

The portion (a) of FIG. 6 shows the difference in magnetic field intensity distribution when the positions of the ends of the write word lines WWL1 and WWL2 are located outside the ends of the magneto-resistive element 11, and the positions of the ends of the conventional write word line wwl coincide with those of the ends of the magneto-resistive element 11. As shown in the portion (b) of FIG. 6, the write word lines WWL1 and WWL2 in the first embodiment are arranged as a square of 100 nm in width×100 nm in height on the same plane at a larger interval of 200 nm than those in the portions (b) of FIGS. 3 and 4. The conventional write word line wwl is a rectangle of 300 nm in width×100 nm in height. In this case, similar to the portion (a) of FIG. 3, the combined magnetic field intensity in the first embodiment decreases at the center of the magneto-resistive element 11, but increases near the end of the magneto-resistive element 11, compared to the prior art. The magnitude of the magnetic field at the end of the magneto-resistive element 11 in the portion (a) of FIG. 6 is larger than that in the portion (a) of FIG. 3. That is, when the interval between the divided write word lines WWL1 and WWL2 is widened, the magnetic field distribution near the magneto-resistive element 11 becomes bimodal, and the maximum value of the magnetic field becomes larger than a value obtained when the wiring is not divided.

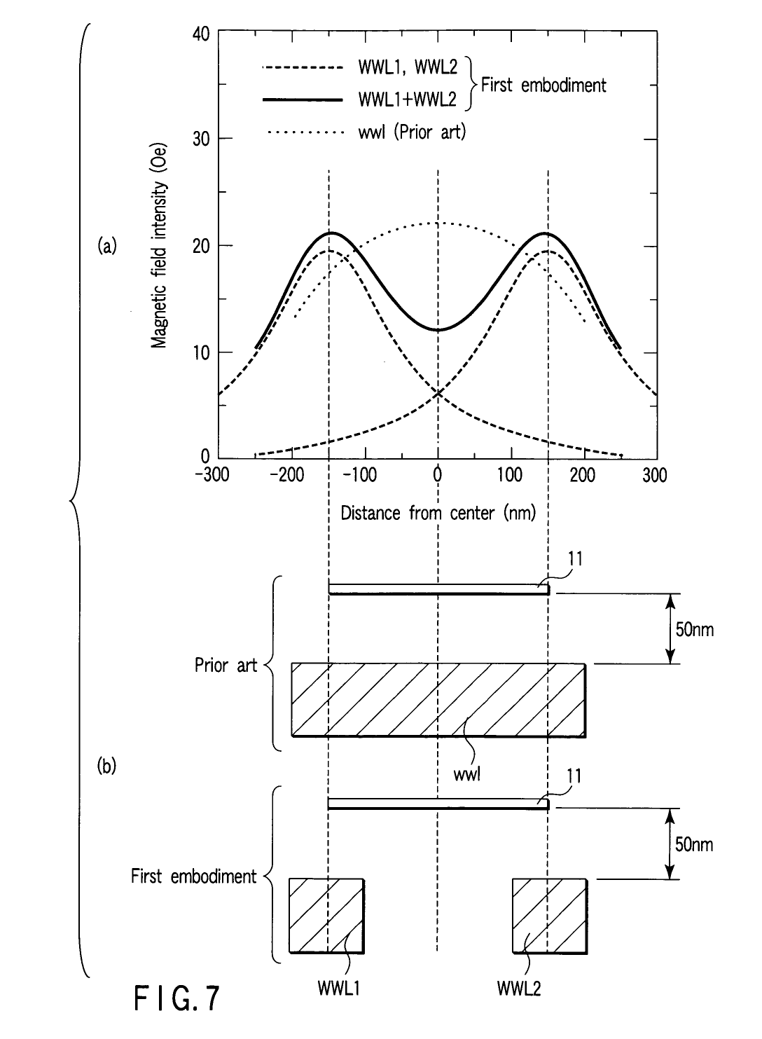

The portion (a) of FIG. 7 shows the difference in magnetic field intensity distribution when the positions of the ends of the write word lines WWL1 and WWL2 and the conventional write word line are located outside the ends of the magneto-resistive element 11. As shown in the portion (b) of FIG. 7, the write word lines WWL1 and WWL2 in the first embodiment are arranged as a square of 100 nm in width×100 nm in height on the same plane at a larger interval of 200 nm than those in the portions (b) of FIGS. 3 and 4. The conventional write word line wwl is a rectangle of 400 nm in width×100 nm in height. In this case, similar to the portion (a) of FIG. 3, the combined magnetic field intensity in the first embodiment decreases at the center of the magneto-resistive element 11, but increases near the end of the magneto-resistive element 11, compared to the prior art.

Magnetization of the magneto-resistive element is switched as follows.

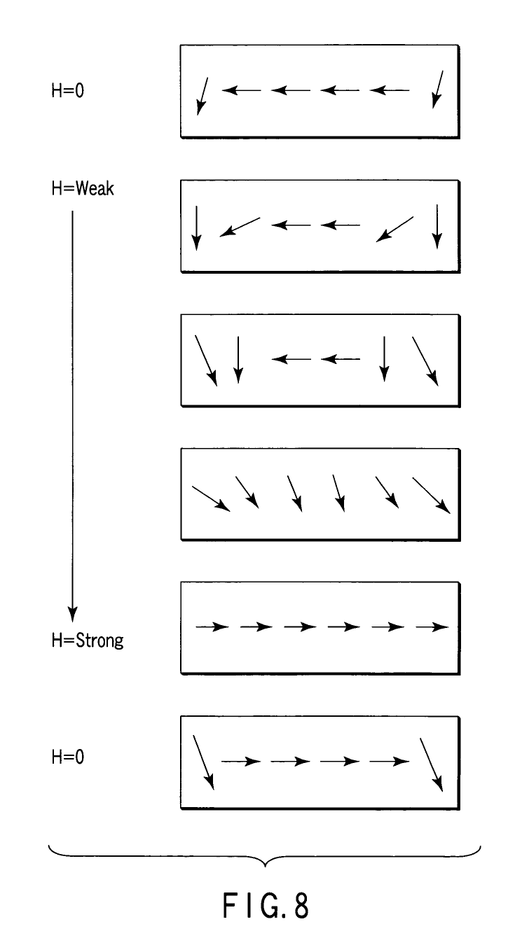

FIG. 8 schematically shows a magnetization state when magnetization of a rectangular magneto-resistive element is switched. From calculation and actual experiments of the dynamic magnetization process, it is known that magnetization switching starts from the end and propagates toward the center in a rectangular ferromagnet about 0.1 μm in width. This finding is obtained when the magnetic field is uniformly applied within the plane of the ferromagnet. However, considering that the magnetization process progresses from generation of a reversed magnetic domain to expansion of the reversed magnetic domain or propagation of the domain wall, as shown in FIG. 8, no magnetic field need be uniformly applied to the magneto-resistive element, unlike the prior art.

More specifically, as shown in the portions (a) of FIG. 3 to FIG. 7, the magnetic field intensity may be different between the end and center of the magneto-resistive element 11, like the magnetic field distribution of the first embodiment. Magnetization switching easily occurs when the magnetic field at the end of the magneto-resistive element 11 is higher than that at the center.

The first embodiment adopts the divided write word lines WWL1 and WWL2 for one magneto-resistive element 11. A magnetic field applied to the magneto-resistive element 11 by the write word line WWL is the combined magnetic field of the write word lines WWL1 and WWL2. To apply the same magnetic field intensity as that applied to the magneto-resistive element 11 by one conventional undivided write word line wwl, a current which is ½ of a current supplied to one write word line wwl suffices to be supplied to each of the write word lines WWL1 and WWL2. By using the divided write word lines WWL1 and WWL2, the write current supplied to each of the write word lines WWL1 and WWL2 can be reduced in comparison with the prior art.

Various magnetic field distributions can be formed for the magneto-resistive element 11 by changing the positions of the write word lines WWL1 and WWL2 to the magneto-resistive element 11 by the interval D between the write word lines WWL1 and WWL2. For example, the write word lines WWL1 and WWL2 are arranged near the ends of the magneto-resistive element 11. This arrangement can increase the magnetic field intensity at the end of the magneto-resistive element 11 more than that at the center, facilitating magnetization switching of the magneto-resistive element 11.

[Second Embodiment]

The first embodiment has exemplified division of the write word line, whereas the second embodiment will exemplify division of the bit line.

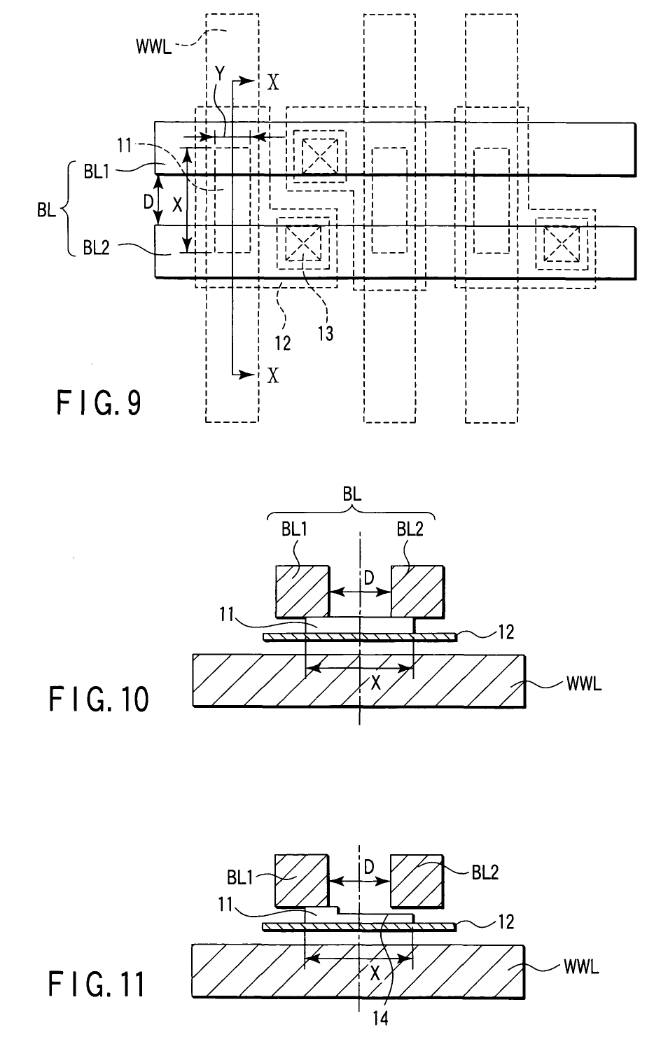

FIG. 9 is a schematic plan view showing a magnetic memory device according to the second embodiment of the present invention. FIG. 10 is a sectional view showing the magnetic memory device taken along the line X-X in FIG. 9.

As shown in FIGS. 9 and 10, the second embodiment is different from the first embodiment in that not a write word line WWL but a bit line BL is divided. In other words, bit lines BL1 and BL2 are arranged on the same plane. The interval D between the bit lines BL1 and BL2 is smaller than the length X of a magneto-resistive element 11. The magneto-resistive element 11 is arranged across the bit lines BL1 and BL2.

Write of data in the magneto-resistive element 11 uses the bit lines BL1 and BL2 and the write word line WWL. Read of data written in the magneto-resistive element 11 uses the bit lines BL1 and BL2 and a switching element.

Since the second embodiment uses the divided bit lines BL1 and BL2, similar to the first embodiment, the write current supplied to each of the bit lines BL1 and BL2 can be reduced in comparison with the prior art.

[Third Embodiment]

The third embodiment is a modification to the second embodiment in which one of divided bit lines is arranged apart from a magneto-resistive element and the other is arranged in contact with the magneto-resistive element.

FIG. 11 is a sectional view showing a magnetic memory device according to the third embodiment of the present invention. As shown in FIG. 11, the third embodiment is different from the second embodiment in that a magneto-resistive element 11 is provided with a step 14, a bit line BL1 is arranged in contact with the magneto-resistive element 11, and a bit line BL2 is arranged apart from the magneto-resistive element 11.

Write of data in the magneto-resistive element 11 uses the bit lines BL1 and BL2 and a write word line WWL. Read of data written in the magneto-resistive element 11 uses the bit line BL1 and a switching element. That is, all the divided bit lines BL1 and BL2 are used in write, and only the bit line BL1 in contact with the magneto-resistive element 11 out of the divided bit lines BL1 and BL2 is used in read.

The third embodiment can obtain the same effects as those of the second embodiment.

In the third embodiment, only the bit line BL1 in contact with the magneto-resistive element 11 out of the divided bit lines BL1 and BL2 is used in read. Thus, the current amount used in reads can be reduced as compared with the second embodiment.

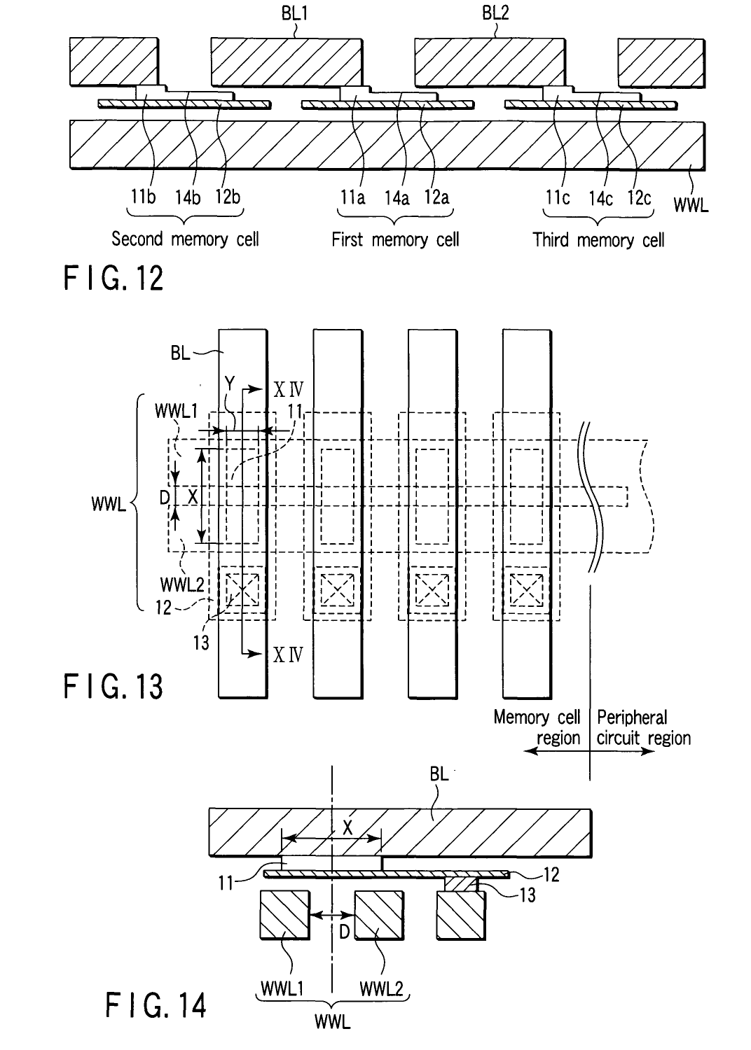

In the third embodiment, the bit lines BL1 and BL2 may be shared between adjacent memory cells. As shown in FIG. 12, the write/read bit line BL1 of the first memory cell is used as the write bit line of the second memory cell. The write bit line BL2 of the first memory cell is used as the write/read bit line of the third memory cell. In FIG. 12, the area occupied by the memory cell region can also be reduced in addition to the effects of the third embodiment.

[Fourth Embodiment]

The fourth embodiment is a modification to the first embodiment in which divided write word lines are connected in a peripheral circuit area.

FIG. 13 is a schematic plan view showing a magnetic memory device according to the fourth embodiment of the present invention. FIG. 14 is a sectional view showing the magnetic memory device taken along the line XIV-XIV in FIG. 13.

As shown in FIGS. 13 and 14, the fourth embodiment is different from the first embodiment in that write word lines WWL1 and WWL2 are connected in the peripheral circuit region outside the memory cell region. The write word lines are divided in the memory cell region, and connected into one in the peripheral circuit region. The wiring pitch of the write word line is different between the memory cell region and the peripheral circuit region.

The fourth embodiment can obtain the same effects as those of the first embodiment.

In the fourth embodiment, the divided write word lines are connected into one wiring. For this reason, the sectional area of the write word line becomes large, and the wiring resistance of the entire chip can be decreased.

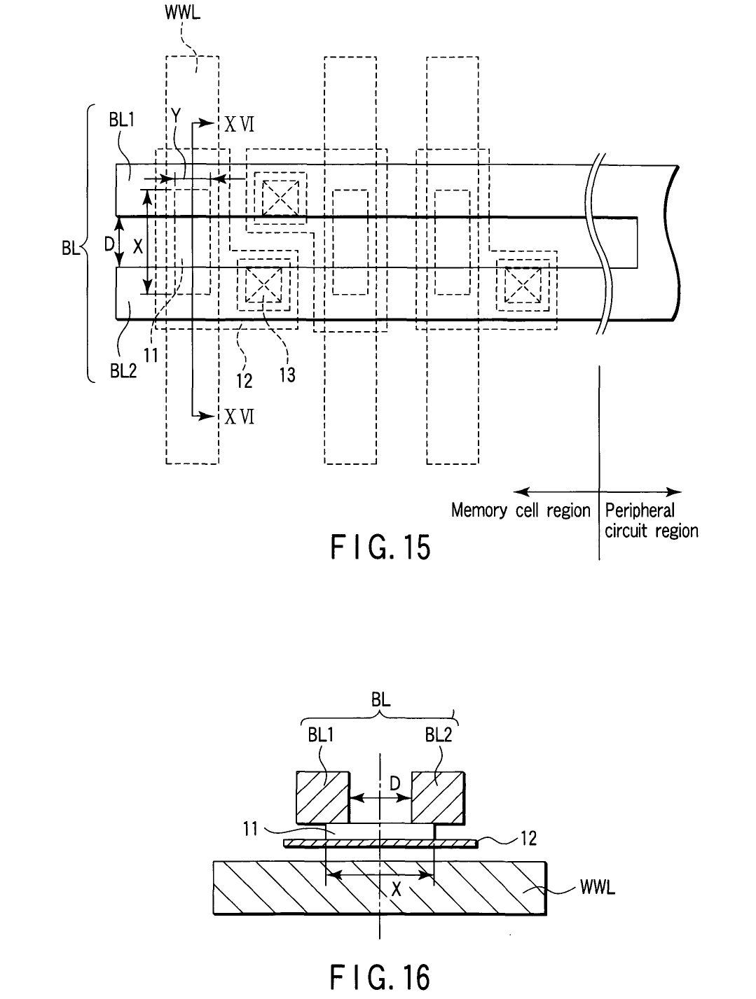

In the fourth embodiment, a bit line BL may be divided, and divided bit lines BL1 and BL2 may be connected in the peripheral circuit region, as shown in FIGS. 15 and 16.

[Fifth Embodiment]

In the first embodiment, all divided write word lines are also used in adjacent cells. In the fifth embodiment, only some of divided write word lines are used in adjacent cells.

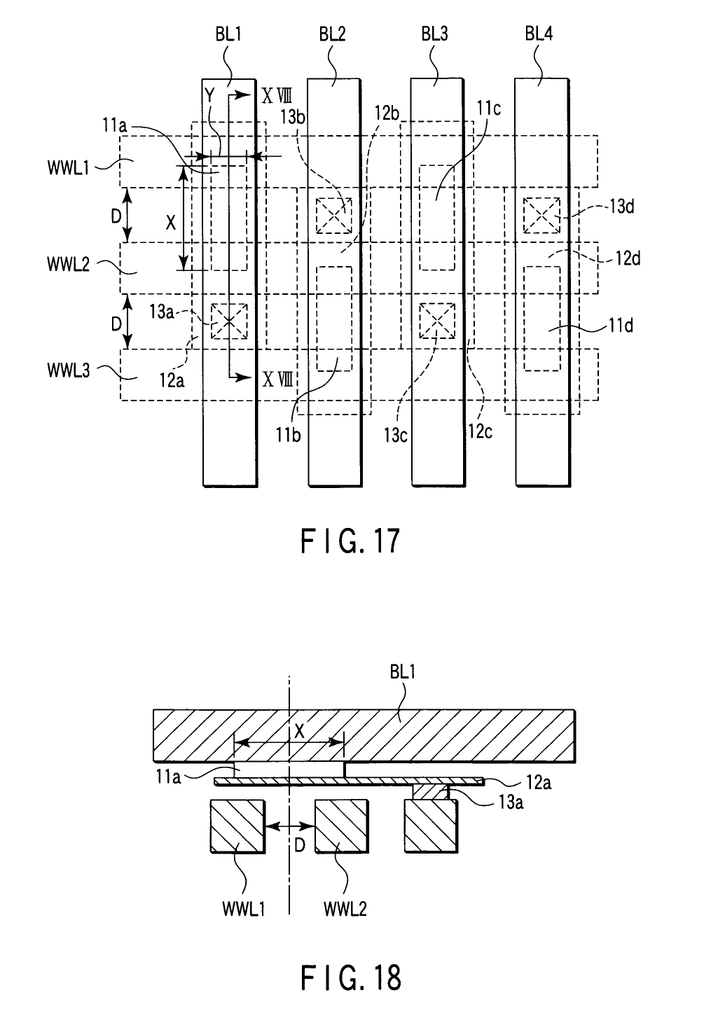

FIG. 17 is a schematic plan view showing a magnetic memory device according to the fifth embodiment of the present invention. FIG. 18 is a sectional view showing the magnetic memory device taken along the line XVIII-XVIII in FIG. 17.

As shown in FIGS. 17 and 18, the fifth embodiment is different from the first embodiment in that magneto-resistive elements 11a, 11b, 11c, and 11d are staggered for divided write word lines WWL1, WWL2, and WWL3, and only the write word line WWL2 is shared between two adjacent cells.

More specifically, write of data in the first magneto-resistive element 11a uses the two write word lines WWL1 and WWL2 and a bit line BL1. Write of data in the second magneto-resistive element 11b uses the two write word lines WWL2 and WWL3 and a bit line BL2. Write of data in the third magneto-resistive element 11c uses the two write word lines WWL1 and WWL2 and a bit line BL3. Write of data in the fourth magneto-resistive element lid uses the two write word lines WWL2 and WWL3 and a bit line BL4.

The fifth embodiment can obtain the same effects as those of the first embodiment.

Moreover, the fifth embodiment can suppress interference between adjacent cells in write. This effect will be explained.

Generally in write, two write word lines are selected, and magnetization of the recording layer of the magneto-resistive element of the selected cell is switched by a combined magnetic field generated at the intersection of the write word lines. In this case, a half-selected cell which receives a magnetic field from any write word line exists in addition to the selected cell, and a write error to the half-selected cell occurs. To prevent such write error, the write current value must be adjusted such that magnetization of a selected cell is switched in write while that of a half-selected cell is not switched. In a large-scale array, the switching magnetic field varies, and the tolerance of the write current value generally decreases.

To prevent this, only some of divided write word lines are used in adjacent cells in the fifth embodiment. When one cell is selected, only one write word line corresponds to an adjacent cell. That is, as shown in FIG. 17, when data is written in the first magneto-resistive element 11a, WWL1, WWL2, and BL1 are selected. Since the write word lines of the second adjacent magneto-resistive element 11b are WWL2 and WWL3, magnetization of the second magneto-resistive element 11b is not switched by only a magnetic field generated by WWL2. Hence, a write error to an adjacent cell can be reduced.

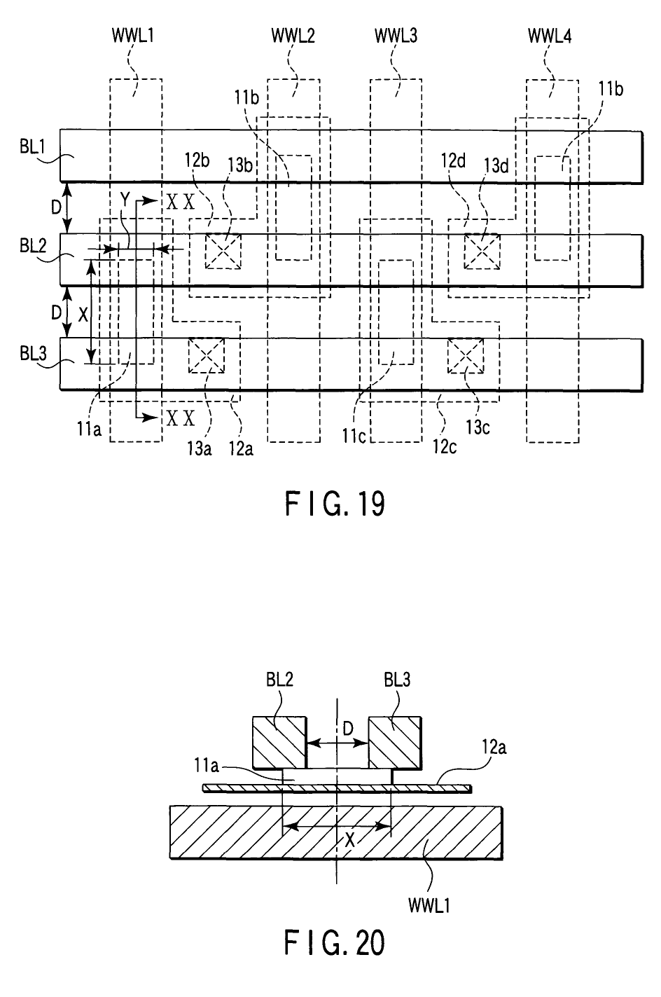

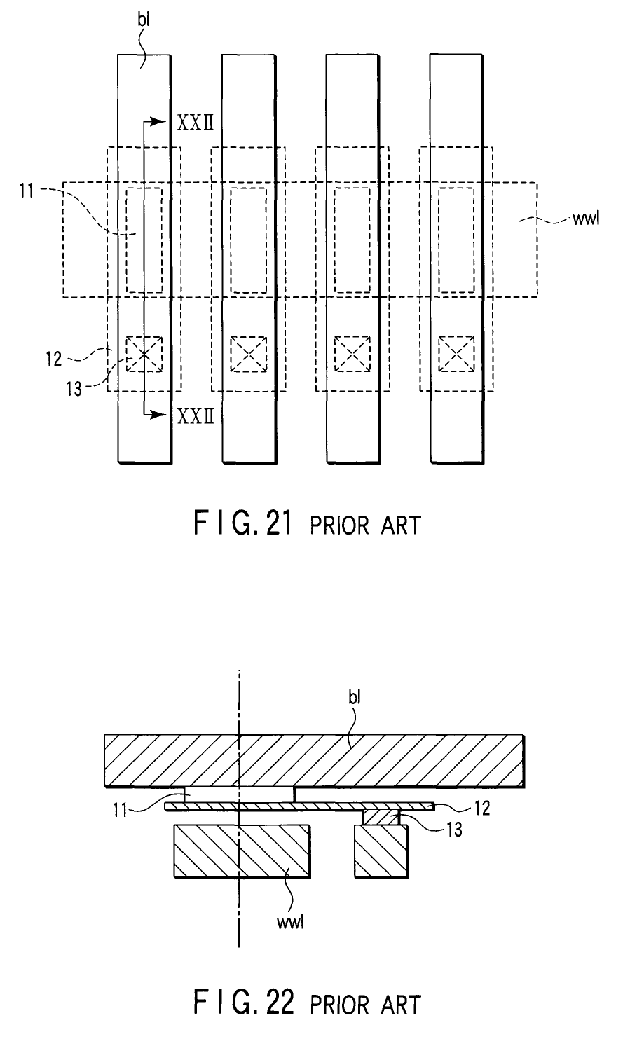

In the fifth embodiment, as shown in FIGS. 19 and 20, the bit line BL may be divided, and only some of divided BL1, BL2, and BL3 may be used in adjacent cells.

The embodiments of the present invention can be variously modified.

For example, the number of divided wirings is two in the first to fifth embodiments for descriptive convenience, but may be three or more.

The word and bit lines need not cross each other at a right angle, and suffice to cross each other at a finite angle.

Both the bit and word lines may be divided. For example, when the bit line BL in FIG. 1 is further divided, the distance between the divided bit lines is desirably smaller than the width Y of the magneto-resistive element.

A width of the divided wiring may be shorter than the length X of the magneto-resistive element. In this case, the write current supplied to the divided wiring can be further reduced.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A magnetic memory device comprising:
first wirings which run in a first direction and are divided in a second direction different from the first direction;
a second wiring which runs in the second direction; and
a first magneto-resistive element which is arranged across the first divided wirings near an intersection of the first and second wirings in a first memory cell region.

2. A device according to claim 1, wherein the first wirings are divided on the same plane.

3. A device according to claim 1, wherein a distance between the first wirings is shorter than a length of the first magneto-resistive element in the second direction.

4. A device according to claim 1, wherein an intensity of a magnetic field generated upon supplying a current to the first wirings has a plurality of maximum values within a plane of the first magneto-resistive element.

5. A device according to claim 4, wherein the maximum value exists at an end of the first magneto-resistive element.

6. A device according to claim 1, wherein the second wiring is divided into a plurality of wirings in the first direction.

7. A device according to claim 6, wherein a distance between the second divided wirings is shorter than a length of the first magneto-resistive element in the first direction.

8. A device according to claim 1, wherein the first wirings include word lines.

9. A device according to claim 1, wherein the first wirings include bit lines.

10. A device according to claim 1, wherein, of the first divided wirings, one wiring is arranged in contact with the first magneto-resistive element, and the other wiring is arranged apart from the first magneto-resistive element.

11. A device according to claim 10, wherein
said one wiring is used as a write/read wiring for the first magneto-resistive element, and
said other wiring is used as a write wiring for the first magneto-resistive element.

12. A device according to claim 10, wherein the first magneto-resistive element has a first step.

13. A device according to claim 10, which further comprises
a second memory cell region adjacent to one side of the first memory cell region,
a third memory cell region adjacent to the other side of the first memory cell region,
a second magneto-resistive element which is arranged in the second memory cell region, and
a third magneto-resistive element which is arranged in the third memory cell region, and
in which said one wiring runs from the first memory cell region into the second memory cell region, and is arranged apart from the second magneto-resistive element, and
said other wiring runs from the first memory cell region into the third memory cell region, and is arranged in contact with the third magneto-resistive element.

14. A device according to claim 13, wherein
said one wiring is used as a write wiring for the second magneto-resistive element, and
said other wiring is used as a write/read wiring for the third magneto-resistive element.

15. A device according to claim 13, wherein
the second magneto-resistive element has a second step, and
the third magneto-resistive element has a third step.

16. A device according to claim 1, wherein the first divided wirings are connected in a peripheral circuit region outside the first memory cell region.

17. A device according to claim 16, wherein a wiring pitch between the first wirings is different between the first memory cell region and the peripheral circuit region.

18. A device according to claim 1, which further comprises
a fourth memory cell region adjacent to the first memory cell region in the first direction, and
a fourth magneto-resistive element which is arranged in the fourth memory cell region, and
in which one of the first divided wirings is used as a write wiring of the fourth magneto-resistive element.

19. A device according to claim 1, wherein a width of each the first wirings is shorter than a length of the first magneto-resistive element in the second direction.
